(19) United States
(12) Patent Application Publication
(10) Pub. No.: US 2008/0029819 A1
(43) Pub. Date: Feb. 7, 2008

(54) SEMICONDUCTOR DEVICE

(75) Inventor: Yasushi HIROSHIMA, Tatsuno-machi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 11/828,106

(22) Filed: Jul. 25, 2007

(30) Foreign Application Priority Data
Aug. 4, 2006 (JP) 2006-212916
May 17, 2007 (JP) 2007-131315

(51) Int. Cl. H01L 27/12

(52) U.S. Cl. 257/352; 257/E27.112

(57) ABSTRACT

A semiconductor device includes a transistor with a semiconductor film formed above a substrate that has at least one insulating surface; a source electrode coupled to a source region of the transistor; and a drain electrode coupled to a drain region of the transistor. The source region and the drain region of the transistor are formed of a plurality of substantially single-crystal grains contained in the semiconductor film. Each of the plurality of substantially single-crystal grains is formed corresponding to one of a plurality of recesses formed in the substrate. Electrical coupling between the drain region and the drain electrode or electrical coupling between the source region and the source electrode is made by using a conductive material disposed in a contact hole. The area of one of the plurality of substantially single-crystal grains is smaller than the sectional area of the contact hole.

### BACKGROUND OF THE INVENTION

1. Technical Field

Several aspects of the present invention relate to a semiconductor device.

2. Related Art

An electro-optical device such as a liquid crystal display or an organic electroluminescent (EL) display uses a thin film circuit that includes a thin film transistor (TFT) as a semiconductor element to perform switching of pixels and other operations.

In hitherto TFTs, an amorphous silicon film is used to form an active region such as a channel formation region.

TFTs using a polysilicon film to form an active region have also been put into a practical use.

By using a polysilicon film, electrical characteristics such as mobility are improved as compared to the case of using an amorphous silicon film, allowing the performances of TFTs to be improved.

To further improve the performances of TFTs, a technique is discussed that forms a semiconductor film made of large crystal grains to avoid a crystal grain boundary entering a channel formation region of a TFT.

For example, a technique is proposed that forms a minute hole on a substrate, and a semiconductor film is crystallized using the minute hole as the starting point of crystal growth so that a silicon crystal grain having a large grain size is formed.

By forming a TFT by use of a silicon film having a large crystal grain size that is achieved by this technique, a crystal grain boundary can be prevented from entering one TFT formation region, particularly a channel formation region.

Thus, TFTs that are excellent in electrical characteristics such as mobility can be realized.

Such a technique is described in, for example, JP-A-2004-186206.

As the performances of a TFT are enhanced, the needs for reducing resistance of a source region and a drain region and reducing variations in their resistance values become obvious.

Even if crystallinity is excellent only in a channel formation region and the resistance in this region decreases in the ON-state of a TFT, carriers (electrons and holes) flow over the whole of a source region and a drain region as well as the channel formation region of the TFT.

Therefore, without sufficiently low resistance of the source region and the drain region and low variations in their resistance values, it is impossible to obtain each TFT, as a whole, having excellent characteristics and TFTs with uniform characteristics.

However, low resistance of the source region and the drain region is not always achieved.

In a general way, an impurity is implanted into a source region and a drain region of a semiconductor film, and thereafter an appropriate heat treatment is performed to recover crystallinity of a portion where the impurity is implanted, thereby activating the impurity.

Since the temperature of a heat treatment at this point needs to be relatively low in the case of using a glass substrate, sufficient activation cannot actually be realized.

The source region and the drain region having relatively high resistance values may therefore be formed.

### SUMMARY

Accordingly, an advantage of the present invention is to provide a high-performance transistor that realizes impurity activation of the source region and the drain region in heat treatment at relatively low temperature and has a low variation in characteristics.

A semiconductor device according to an aspect of the invention includes: a transistor with a semiconductor film formed above a substrate, the substrate having at least one insulating surface; a source electrode coupled to a source region of the transistor; and a drain electrode coupled to a drain region of the transistor; the source region and the drain region of the transistor being formed of a plurality of substantially single-crystal grains contained in the semiconductor film; each of the plurality of substantially single-crystal grains being formed corresponding to one of a plurality of recesses formed in the substrate; one of electrical coupling between the drain region and the drain electrode and electrical coupling between the source region and the source electrode being made by using a conductive material disposed in a contact hole; an area of one of the plurality of substantially single-crystal grains being smaller than a sectional area of the contact hole.

In the above-mentioned semiconductor device, a plurality of substantially single-crystal grains with high-quality, which are formed with a recess as the starting point, can be included in a contact hole.

Therefore, effects of a variation in activation caused by a variation in crystal orientation among substantially single-crystal grains can be reduced in activating an impurity element introduced into the source region and the drain region by a heat treatment.

This reduction allows a transistor to have a low variation in contact resistance of a semiconductor film in the source region and the drain region with respect to the source electrode and the drain electrode.

A semiconductor device according to another aspect of the invention includes: a transistor with a semiconductor film formed above a substrate, the substrate having at least one insulating surface; a source electrode coupled to a source region of the transistor; and a drain electrode coupled to a drain region of the transistor; the source region and the drain region of the transistor being formed of a plurality of substantially single-crystal grains contained in the semiconductor film; each of the plurality of substantially single-crystal grains being formed corresponding to one of a plurality of recesses formed in the substrate; the drain region and the drain electrode or the source region and the source electrode being electrically coupled through a conductive material disposed in a plurality of contact holes.

In the above-mentioned semiconductor device, it is preferable that the conductive material disposed in a first one of the plurality of contact holes be in contact with at least part of a first one of the plurality of substantially single-crystal grains and the conductive material disposed in a second one of the plurality of contact holes that is different from the first one of the plurality of contact holes is in contact with at least part of a second one of the plurality of substantially single-crystal grains that is different from the first one of the plurality of substantially single-crystal grains.

In the above-mentioned semiconductor device, it is preferable that the total sectional area of the plurality of contact holes be larger than that of one of the plurality of substantially single-crystal grains.

In the above-mentioned semiconductor device, it is preferable that the area of one of the plurality of substantially single-crystal grains be equal to or larger than that of one of the plurality of contact holes.

A semiconductor device according to a still another aspect of the invention comprises: a transistor with a semiconductor film formed above a substrate, the substrate having at least one insulating surface; a source electrode coupled to a source region of the transistor; and a drain electrode coupled to a drain region of the transistor; the source region and the drain region of the transistor being formed of a plurality of substantially single-crystal grains contained in the semiconductor film; each of the plurality of substantially single-crystal grains being formed corresponding to one of a plurality of recesses formed in the substrate; one of electrical coupling between the drain region and the drain electrode and electrical coupling between the source region and the source electrode being made by a conductive material disposed in a contact hole; the conductive material being in contact with at least two of the plurality of substantially single-crystal grains.

In the above-mentioned semiconductor device, it is preferable that the conductive material be in contact with grain boundaries made by one of the two substantially single-crystal grains and all substantially single-crystal grains in contact with the one substantially single-crystal grain.

In the above-mentioned semiconductor device, for example, if only a single substantially single-crystal grain or part thereof is included in each contact hole, the source electrode and the drain electrode can be substantially coupled to a plurality of substantially single-crystal grains by forming a plurality of contact holes corresponding to each of the source region and the drain region.

Therefore, even if activation of an impurity element by a heat treatment after introducing an impurity has a variation due to crystal orientations of substantially single-crystal grains, effects of the variation can be reduced, as a whole, since contact holes are formed for the plurality of substantially single-crystal grains.

Thus, a transistor that has a low variation in contact resistance of a semiconductor film in the source region and the drain region with respect to the source electrode and the drain electrode can be formed.

Note that the term “substantially single-crystal grain” as used herein can include ordered grain boundaries (coincidence grain boundaries) such as Σ3, Σ9 and Σ27.

### BRIEF DESCRIPTION OF THE DRAWINGS

The invention will be described with reference to the accompanying drawings, wherein like numbers reference like elements.

FIGS. 1A through 1E are explanatory views illustrating a process of forming a minute hole and forming a substantially single-crystal grain of silicon.

FIG. 2 is an explanatory view illustrating a process of forming a substantially single-crystal grain of silicon.

FIGS. 3A through 3C are plan views illustrating a relationship between placement of minute holes and the shapes of substantially single-crystal grains formed corresponding to the placement, if substantially single-crystal grains of silicon are formed.

FIGS. 4A and 4B are plan views primarily illustrating a gate electrode and an active region (a source region, a drain region and a channel formation region), with other portions in the configuration omitted.

FIGS. 5A through 5C are explanatory views illustrating a process of forming a TFT.

FIGS. 6A through 6C are explanatory views illustrating a relationship between the size P of a substantially single-crystal grain of a source region or a drain region and the size S of a contact hole.

FIG. 7 is a diagram illustrating a connection state of a display that is one example of an electro-optical device.

FIGS. 8A through 8F illustrate examples of electronic apparatus to which a display can be applied.

### DESCRIPTION OF EXEMPLARY EMBODIMENT

An embodiment of the invention will now be described with reference to the accompanying drawings.

Description will be given along a method for manufacturing a TFT for ease of explanation.

The method includes (1) a process of forming a minute hole as a recess in the invention on a substrate, the minute hole functioning as the starting point of crystallizing a silicon film, which is a semiconductor film; (2) a process of growing and forming a silicon crystal grain from the minute hole; and (3) a process of forming a TFT using a silicon film having the silicon crystal grain.

Each process will be described below in detail.

(1) Minute Hole Formation Process

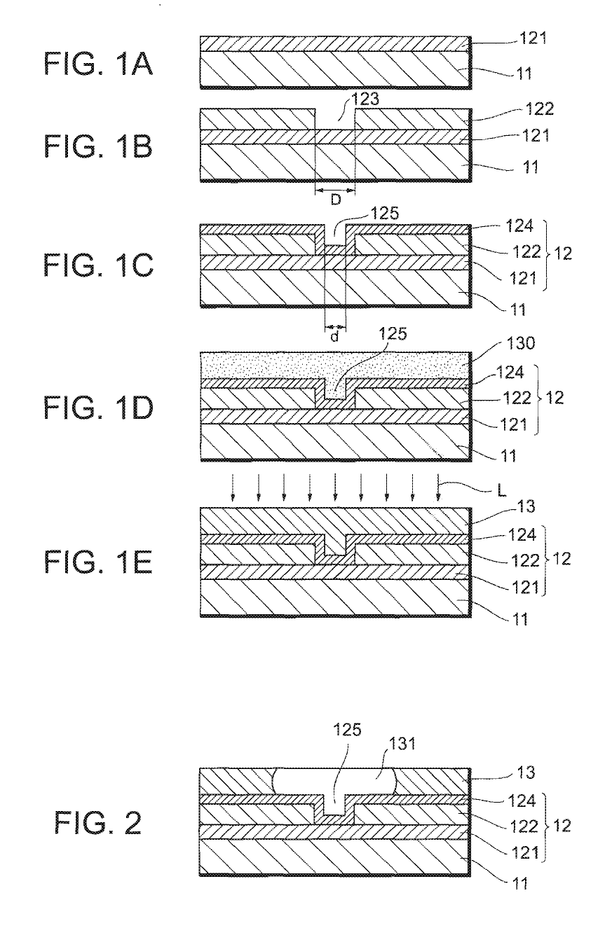

As shown in FIG. 1A, a silicon oxide film 121 as a substrate insulating film is formed on a substrate 11 made of glass or quartz.

The film thickness is, for example, about 200 nm.

A silicon oxide film having a thickness of 550 nm is next formed on the substrate insulating film 121 as a first insulating film 122.

A hole 123 having a diameter of about 1 μm or less is then formed in the first insulating film 122 (FIG. 1B).

In order to form the hole 123, a photoresist film applied over the first insulating film 122 is exposed and developed using a mask so that a photoresist film (not shown) with an opening for exposing a formation portion of the hole 123 is formed on the first insulating film 122.

Subsequently, reactive ion etching is performed using the photoresist film as an etching mask, and thereafter the photoresist film is removed, resulting in formation of the hole 123.

Next, a silicon oxide film as a second insulating film 124 is formed on the first insulating film 122 with the hole (FIG. 1C).

By adjusting the deposited film thickness of the second insulating film 124, the diameter of the hole 123 is reduced.

As a result, a minute hole 125 having a diameter of about 20 to 150 nm is formed as a recess in the invention.

The substrate insulating film 121, the first insulating film 122 and the second insulating film 124 (hereinafter, these layers also being referred together to as an insulating layer 12) each can be formed by a PECVD (plasma-enhanced chemical-vapor deposition) method using a material such as TEOS (tetraethyl orthosilicate) or silane (SiH₄) gas.

The minute holes 125 are formed for a channel formation region, a source region and a drain region of a TFT to be formed in a process that will be described later.

At this point, the distance intervals between adjacent minute holes are preferably about 6 μm or less.

This interval size approximately corresponds to the size (diameter) of a silicon crystal grain that grows from each minute hole 125 by laser illumination to be described later.

The intervals of minute holes 125 may differ by place.

For example, the intervals of minute holes may differ between the channel formation region and the source region or the drain region.

Different intervals of minute holes permit the size of single-crystal grains to be adjusted according to desired characteristics and performances for the channel formation region and the source region or the drain region.

(2) Crystal Grain Formation Process

As shown in FIG. 1D, an amorphous silicon film 130 to be used as a semiconductor film is formed on a silicon oxide film, which functions as the above-mentioned second insulating film 124, and in the above-mentioned minute hole 125 by a film formation method such as an LPCVD (low-pressure chemical vapor deposition) method or a PECVD method.

The amorphous silicon film 130 is preferably formed with a film thickness of about 50 to 300 nm.

A polysilicon film may be formed instead of the amorphous silicon film 130 (hereinafter, these layers each also being referred to as a silicon film 13).

Note that if the silicon film 13 is formed by an LPCVD method or a PECVD method, the formed silicon film 13 can contain relatively much hydrogen. In such a case, a heat treatment should be performed to reduce the amount of hydrogen contained in the silicon film, preferably to be 1% or less, in order to prevent ablation of the silicon film 13 during laser illumination to be described below.

Next, as shown in FIG. 1E, the silicon film 13 is exposed to laser illumination L.

The laser illumination is preferably performed using a XeCl pulse excimer laser with a wavelength of 308 nm and a pulse width of 20 to 30 ns or a XeCl excimer laser with a pulse width of about 200 ns so that the energy density is about 0.4 to 2.0 J/cm².

By performing laser illumination under such conditions, illuminated laser light is efficiently absorbed near the surface of the silicon film.

This is because the amorphous silicon has a relatively large absorption coefficient of 0.139 nm⁻¹ at the wavelength (308 nm) of the XeCl pulse excimer laser.

By appropriately selecting the conditions of the laser illumination L, part of the silicon film is made to remain in a non-molten state in the bottom of the minute hole 125, and the other parts are made to be in a completely molten state or a state near the completely molten state (a substantially completely molten state).

The crystal growth of silicon after the laser illumination therefore starts in the vicinity of the bottom of the minute hole, and proceeds to a portion near the surface of the silicon film 13, that is, a portion in a completely molten state or a substantially completely molten state.

Even if the energy of the laser illumination L is slightly stronger than that in this case such that a portion in a non-molten state does not remain in the bottom of the minute hole 125, the crystal growth of silicon after the laser illumination can start in the vicinity of the bottom of the minute hole 125, and proceeds to the portion near the surface of the silicon film 13 due to a temperature difference between the bottom of the minute hole 125 and the portion near the surface of the silicon film 13.

In the initial stage of silicon crystal growth, several crystal grains can be generated in the bottom of the minute hole 125.

At this point, the section size (diameter of a circle in the embodiment) of the minute hole 125 is set nearly equal to or slightly less than that of one crystal grain so that only one crystal grain reaches the top (opening) of the minute hole 125.

Therefore, in a portion in a substantially completely molten state of the silicon film 13, the crystal growth proceeds with one crystal grain that has reached the top of the minute hole 125 functioning as the nucleus.

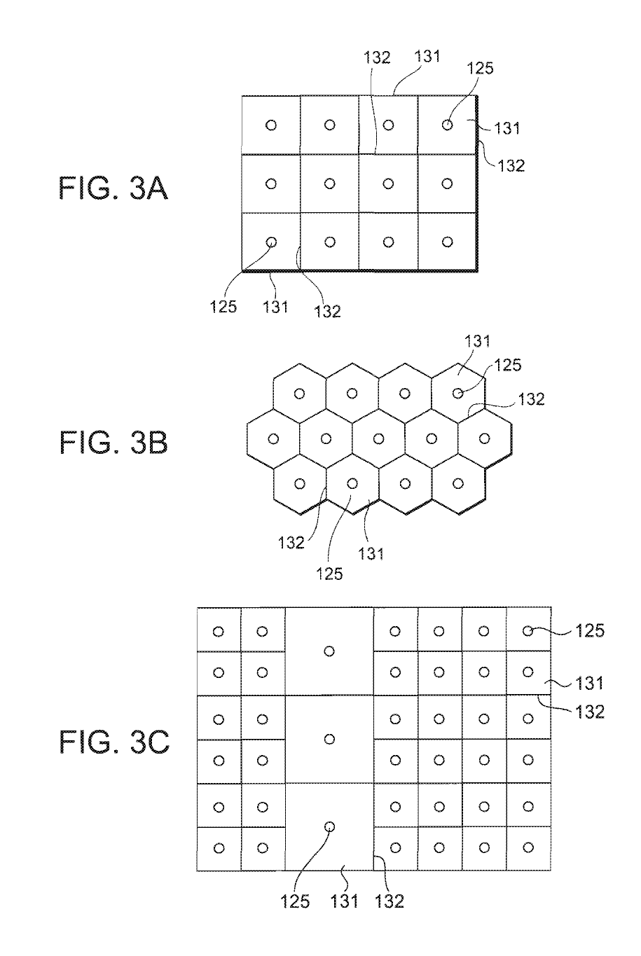

This allows formation of a silicon film that includes substantially single-crystal grains of silicon 131 regularly arranged as shown in FIG. 3A.

Each substantially single-crystal grain of silicon 131 has the large grain size, and is provided with the minute hole 125 substantially centered therein.

The wording “substantially centered” as used herein not only means being geometrically centered.

The term also means that since the minute hole functions as the starting point of the crystal growth as mentioned above, the minute hole is to be positioned around the middle of a substantially single-crystal grain immediately after the crystal growth.

The term “substantially single-crystal grain” as used herein can include ordered grain boundaries (coincidence grain boundaries) such as Σ3, Σ9 and Σ27.

The above-described method for forming a substantially single-crystal grain can suppress disordered grain boundaries including many silicon unpaired electrons.

Portions with high reaction activity such as unpaired electrons or dangling bond generally exist in disordered grain boundaries.

This constitutes a major cause of reduction of characteristics and a variation in characteristics in a transistor.

However, by using the above-described method, a transistor with excellent characteristics can be obtained.

At this point, if the minute hole 125 has a large diameter of about 150 nm or more, a plurality of crystal grains are generated in the bottom of the minute hole 125 and grow to reach the top of the minute hole.

Therefore, disordered grain boundaries tend to be generated.

Note that, in the above-described crystallization by the laser illumination L, it is also preferable to heat the substrate 11 in addition to the laser illumination L.

For example, a heat treatment is preferably performed using a stage for mounting the substrate 11 so that the temperature of the glass substrate is about 200 to 400° C.

Such simultaneous use of laser illumination and substrate heating makes it possible to further increase the crystal grain size of the substantially single-crystal grain of silicon 131.

The crystal grain size can be increased to be about 1.5 to 2 times greater than that in use of laser illumination only.

Further, there is an advantage in that crystallinity of the substantially single-crystal grain of silicon further improves because the simultaneous use of laser illumination and substrate heating makes the progress of crystallization slow.

As described above, by forming the minute hole 125 in a desired location on the substrate 11, the substantially single-crystal grain of silicon 131 with relatively excellent crystallinity can be formed with the minute hole 125 substantially centered after laser illumination.

It was confirmed that crystallinity was particularly excellent in portions other than the portion near the minute hole 125 in the crystal grain 131, and continuous crystallinity was maintained in the film thickness direction (no coincidence grain boundary in parallel to the in-plane direction).

It was also confirmed that there was no preferred crystal orientation among the substantially single-crystal grains of silicon 131.

That is, it was confirmed that they had substantially random orientations.

On the other hand, a portion of the silicon film 13 where the minute hole 125 is not formed (a portion of the silicon film 13 sufficiently apart from the minute hole 125) is made to be in a substantially completely molten state by laser illumination.

After the laser illumination, since the isotropic nucleus generation and crystal growth proceeds, a polysilicon film containing microcrystalline grains is formed.

In the polysilicon film, crystal grains of about 0.5 μm or less are randomly arranged, although depending on conditions of laser illumination.

(3) Transistor Formation Process

Next, description will be given on the structure of a transistor formed using the above-described silicon film.

Currently, the crystal grain size of the substantially single-crystal grain of silicon 131 obtained by crystallization with the minute hole 125 functioning as the starting point can be achieved to be up to about 6 μm.

A process of forming a transistor T will be described.

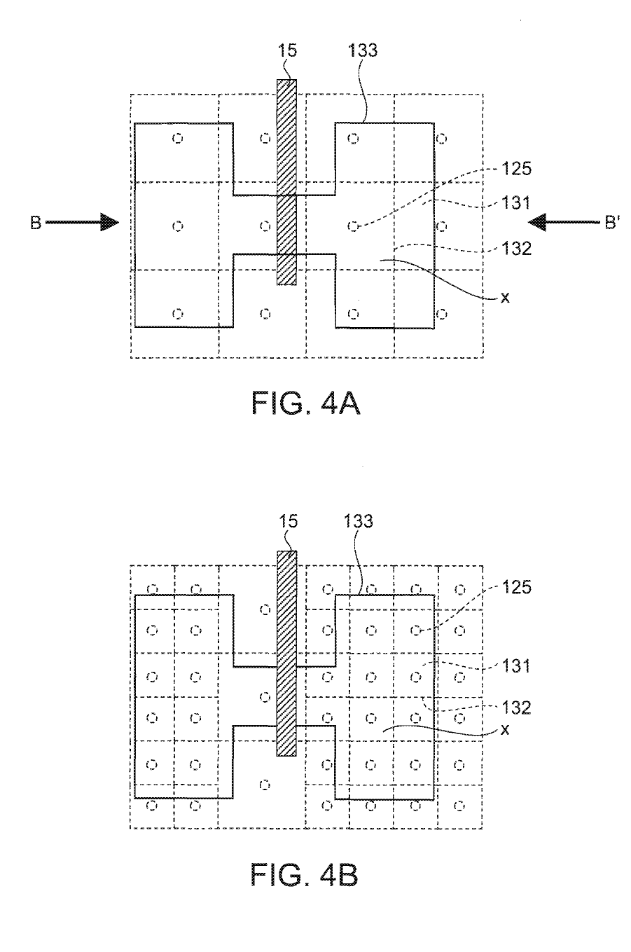

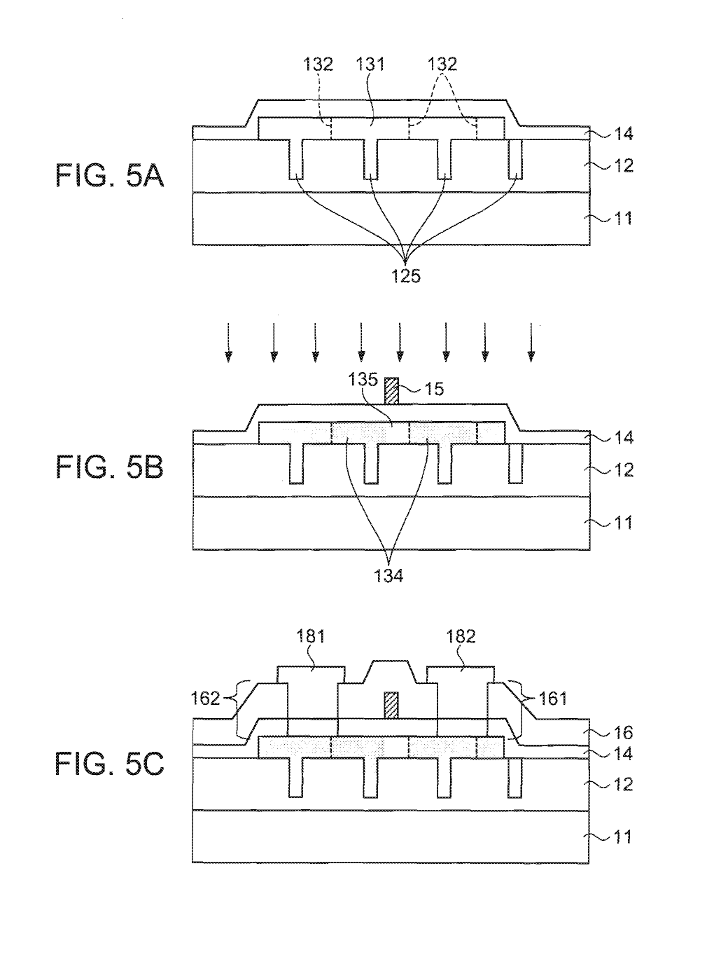

FIGS. 4A and 4B and FIGS. 5A through 5C are explanatory views illustrating a process of forming the TFT T.

FIGS. 4A and 4B are plan views of the completed TFT, and FIGS. 5A through 5C are sectional views taken along the line B-B′ of FIG. 4A.

A plurality of substantially single-crystal grains of silicon 131 can be formed to be in contact with each other by arranging a plurality of minute holes 125 at intervals of 6 μm or less as shown in FIG. 3A.

The method for arranging the minute holes 125 is appropriately selected according to characteristics and performances of a desired transistor.

For example, a method of arranging the minute holes 125 at regular intervals from side to side and up and down as shown in FIG. 3A, and a method of arranging the adjacent minute holes 125 at equal intervals as shown in FIG. 3B are conceivable.

As shown in FIG. 3C, the intervals between the minute hole 125 may also differ between a channel formation region and a source region or a drain region that will all be formed later.

The silicon film in which a plurality of substantially single-crystal grains of silicon 131 are arranged is patterned such that a portion unrequired for transistor formation is removed from the silicon film to thereby form a patterned silicon film 133.

At this point, it is desirable for a portion to be a channel formation region 135 of a transistor not to include the minute hole 125 and the vicinity thereof.

This is because disorder of crystallinity tends to occur in the minute hole 125 and the vicinity thereof.

A plurality of minute holes 125 are formed so that the plurality of substantially single-crystal grains are disposed in portions to be a source region and a drain region 134, and particularly in portions that are to be the source region and the drain region 134 and correspond to places where contact holes will be formed in a later process (FIGS. 4A and 4B).

Next, as shown in FIG. 5A, a silicon oxide film 14 is formed on the top surfaces of the silicon oxide film 124 (12), which is the second insulating film, and the patterned silicon film 133 by a method such as an ECR (electron cyclotron resonance)-PFCVD method, a parallel plate type PECVD method or plasma oxidation using oxygen plasma.

The silicon oxide film 14 functions as a gate insulating film of a TFT, and preferably has a film thickness of 10 to 150 nm.

Then, as shown in FIG. 5B, a metal thin film of tantalum, aluminum or the like is formed by a film formation method such as sputtering, and thereafter the film is patterned to form a gate electrode 15 and a gate wiring film.

By performing so-called self-aligned ion implantation that implants an impurity element to be donors with the gate electrode 15 used as a mask, the source region and drain region 134 and the channel formation region 135 of an N-channel TFT is formed in the silicon film 133.

For example, phosphor (P) is implanted as the impurity element in the embodiment.

This causes damage to the crystallinity in the vicinity of the surface of the silicon film, which contains substantially single-crystal grains, positioned in the source region and the drain region, resulting in a crystal defect.

However, since a portion with excellent crystallinity (crystal layer) remains under the damaged portion, a heat treatment at temperatures around 450° C. or more is performed.

As a result, the damage of the crystal defect is recovered by solid phase epitaxial growth (to be described later) from the crystal layer in the lower portion.

At the same time, phosphor enters the crystal lattice position of silicon to be electrically activated.

Therefore, the source region and drain region 134 can have reduced resistance.

Similarly, in the case of forming a P-channel TFT, boron (B) is widely used as an impurity element that functions as acceptors.

The activation rate of boron by a later heat treatment is relatively low, resulting in relatively high resistance of the source region and the drain region of a P-channel TFT.

This is because the mass of a boron element is less than that of a silicon element, and therefore the damage to crystallinity of the silicon film 133 is minor with a normal implanting amount (dose amount), making it difficult for boron to enter the lattice position of silicon.

Accordingly, ions of a group-IV element such as silicon or germanium are implanted into the silicon film 133 with the gate electrode 15 used as a mask to impair the crystallinity near the surfaces of the source region and drain region, thereby forming an amorphous layer.

Thereafter, boron is implanted, which will be an acceptor impurity.

At this point, it is desirable that the depth (range center-to-center distance) of the implantation of group-IV element ions into the silicon film 133 be substantially equal to that of the implantation of boron.

Specifically, it is the most desirable to adjust the depth to be about 10 nm from the surface of the silicon film 133.

By these operations, an amorphous layer containing boron is formed near the surface of the silicon film, which contains substantially single-crystal grains, positioned in the source region and the drain region, and a crystal layer with excellent crystallinity is formed under the amorphous layer.

As a heat treatment is applied to these layers at temperatures around 450° C. or more, solid phase epitaxial growth proceeds in the amorphous layer using the crystal layer thereunder as a seed layer.

In the process, boron functioning as an impurity element efficiently enters a lattice position of a silicon crystal structure, achieving activation.

This enables the source region and the drain region to have significantly lower resistance than conventional one.

It was confirmed by an experiment that the resistance was reduced to about one fifth of the conventional one.

It is known, however, that rapidity of the above-mentioned solid phase epitaxial growth strongly depends on the crystal orientation of silicon.

For example, if heat treatment is applied at relatively low temperatures around 450° C., the progress of the solid phase epitaxial growth differs among individual substantially single-crystal grains due to their random crystal orientations.

This causes a great variation in contact resistance when substantially single-crystal grains each come in contact with the source electrode and the drain electrode that are described later.

This resistance variation further causes a variation in characteristics of a transistor.

To address this problem, the invention provides a structure to be described later to reduce the variation.

After the above-described impurity has been implanted, a silicon oxide film 16 having a film thickness of about 500 nm is formed on the top surface of a silicon oxide film constituting the gate insulating film 14, and the gate electrode 15 by a film formation method such as a PECVD method, as shown in FIG. 5c.

The silicon oxide film 16 functions as an interlayer insulating film.

After the silicon oxide film 16 has been formed, the above-described heat treatment to activate an impurity may be performed.

Next, contact holes 161 and 162 are formed that pass through the interlayer insulating film 16 and the gate insulating film 14, and reach the source region and the drain region.

These contact holes are filled with metal such as aluminum, tungsten or the like by a film formation method such as sputtering, and is patterned to form a source electrode 181 and a drain electrode 182.

At this point, it is preferable that a conductive material placed in the contact holes 161 and 162 be in contact with at least two substantially single-crystal grains of the plurality of substantially single-crystal grains.

Further, it is preferable that the plurality of substantially single-crystal grains of silicon 131 that have grown from the minute holes 125 be disposed in portions of the silicon film 131 that are located at places of the contact holes 161 and 162 and are in contact with the source electrode 181 and the drain electrode 182.

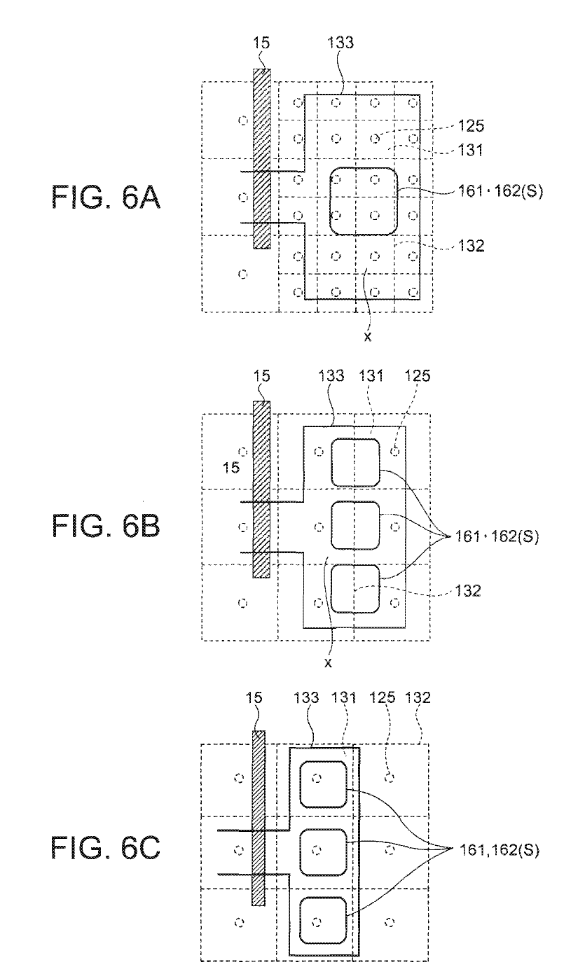

FIGS. 6A through 6C are plan views illustrating the minute holes 125 in the source region or the drain region, the substantially single-crystal grains 131 and the contact hole 161 or 162.

FIG. 6A shows an individual contact hole 161 or 162 formed over a plurality of substantially single-crystal grains 131.

FIG. 6B shows individual contact holes 161 or 162 formed over two substantially single-crystal grains 131.

FIG. 6C shows individual contact holes 161 or 162 formed to be within one substantially single-crystal grain 131.

Although these all present effects of the invention, it is more preferable that the contact holes 161 and 162 be disposed so that a relation ship P<S holds, where S is the size (the area of an opening formed in the silicon oxide film 14) of the contact hole 161 or 162, and P is the size (sectional area) of the substantially single-crystal grain 131 formed in the contact hole portion, as shown in FIG. 6A.

As described above, the resistance of portions of substantially single-crystal grains of silicon is reduced by activation of an impurity element.

However, the degrees of activation differ among individual substantially single-crystal grains of silicon due to their differences in crystal orientation.

This causes a variation in their contact resistance.

In a semiconductor device of the invention, substantially single-crystal grains 131 and the contact holes 161 and 162 are formed with a relationship P<S.

Therefore, a plurality of substantially single-crystal grains can be disposed in a single contact hole.

As a result, the variation among substantially single-crystal grains is reduced.

This allows good electrical joining accompanying a less variation of the source electrode 181 and the drain electrode 182, which are metal films, with the silicon film 133.

In the structure of a semiconductor device according to another aspect of the invention, the drain region and the drain electrode or the source region and the source electrode are electrically coupled through a conductive material provided in a plurality of contact holes.

For example, when the size P of the substantially single-crystal grain 131 and the size S of a contact hole are in a relationship P≧S, a plurality of contact holes are formed in each of a source region and a drain region (FIG. 6B).

Since each contact hole has an area equal to or less than that one substantially single-crystal grain 125, the contact resistance has a variation among individual contact holes due to the reason mentioned above.

By forming a plurality of contact holes in each of the source region and drain region 134, a source electrode and a drain electrode are substantially coupled to a plurality of substantially single-crystal grains.

This reduces the variation of the contact resistance.

In the TFT, as a whole, good electrical joining accompanying a less variation of the source electrode 181 and the drain electrode 182, which are metal films, with the silicon film 133 can thus be achieved.

Additionally, it is desirable in order to further reduce the variation that the number of contact holes be determined so that the total of areas S of the openings is larger than an area P of the substantially single-crystal grain 131 formed in the source region and the drain region.

By the manufacturing method described above, a TFT in the embodiment is formed.

Next, examples of applying a TFT of the invention will be described.

The TFT of the invention can be utilized as a switching element of a liquid crystal display or a driving element of an organic EL display.

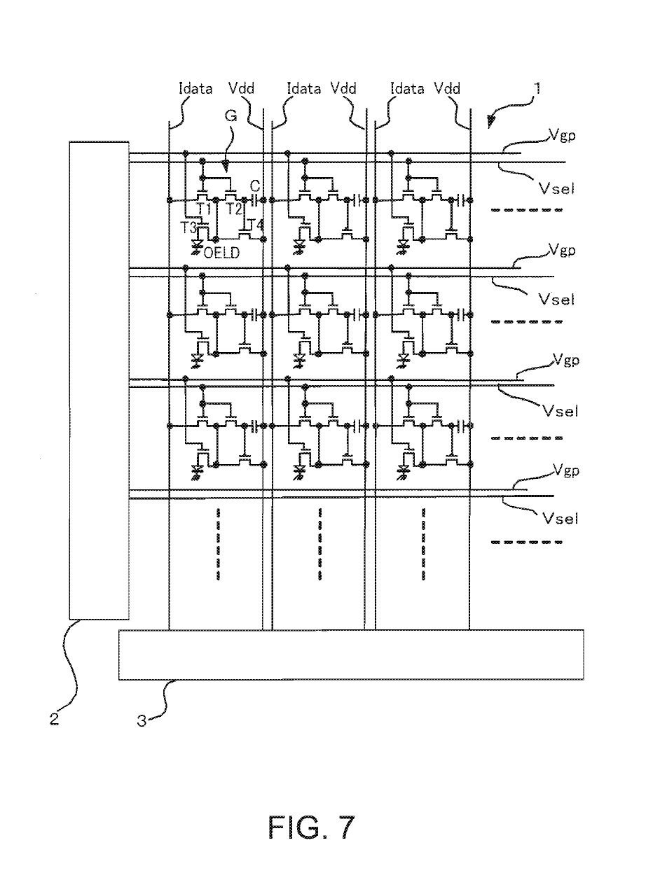

FIG. 7 is a diagram illustrating a connection state of a display 1, which is one example of an electro-optical device of the embodiment.

As shown in FIG. 7, a display 1 includes pixel regions G arranged in display regions.

Each pixel region G uses TFTs T1 to T4 that drive an organic EL light-emitting element OELD.

TFTs manufactured using a manufacturing method of the above-described embodiment are used as the TFTs T1 to T4.

A driver region 2 supplies a light-emitting control line (Vgp) and a write control line (Vsel) to each pixel region G.

A driver region 3 supplies a current line (Idata) and a power source line (Vdd) to each pixel region G.

A current program for each pixel region G is performed by controlling the write control line Vsel and the current line Idata, and light-emitting is controlled by controlling the light-emitting control line Vgp.

In the TFTs T1 to T4 in the embodiment, a transistor of the invention can be used for the driver regions 2 and 3.

This is particularly useful for applications requiring large current such as a buffer circuit included in the driver regions 2 and 3 that selects the light-emitting control line Vgp and the write control line Vsel.

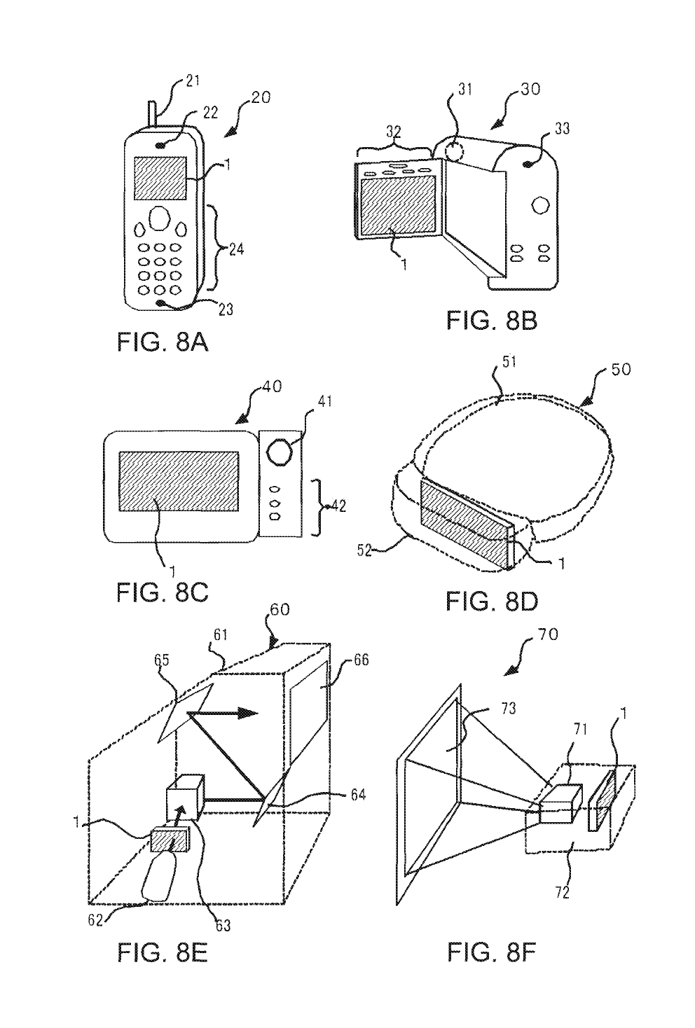

FIGS. 8A through 8F illustrate examples of electronic apparatus to which the display 1 can be applied.

The above-described display 1 can be applied to various electronic apparatus.

FIG. 8A illustrates an example of application to a cellular phone.

The cellular phone 20 includes an antenna section 21, a sound output section 22, a sound input section 23, an operation section 234 and the display 1 of the invention.

In this way, the display 1 of the invention can be used as a display section.

FIG. 8B illustrates an example of application to a video camera.

The video camera 30 includes a picture section 31, an operation section 32, a sound input section 33 and the display 1 of the invention.

In this way, the display 1 of the invention can be used as a finder and a display.

FIG. 8C illustrates an example of application to a portable personal computer, which is specifically a so-called PDA (personal digital assistant).

The computer 40 includes a camera section 41, an operation section 42 and the display 1 of the invention.

In this way, the display 1 of the invention can be used as a display.

FIG. 8D illustrates an example of application to a head-mount display.

The head-mount display 50 includes a band 51, an optical system storage section 52 and the display 1 of the invention.

In this way, a display panel of the invention can be used as an image display source.

FIG. 8E illustrates an example of application to a rear projector.

The rear projector 60 includes a light source 62, a composite optical system 63, mirrors 64 and 65, a screen 66 and the display 1 of the invention in an enclosure 61.

In this way, the display 1 of the invention can be used as an image display source.

FIG. 8F illustrates an example of application to a front projector.

The front projector 70 includes an optical system 71 and the display 1 of the invention in an enclosure 72, and can display an image on a screen 73.

In this way, a display of the invention can be used as an image display source.

Application examples of the display 1 using a transistor of the invention are not limited to those described above.

The display 1 can be applied to any electronic apparatus to which active and passive matrix liquid crystal displays and organic EL displays are applicable.

For example, the display 1 can be used for fax machines with display functions, finders of digital cameras, portable TVs, electronic notebooks, electronic billboards and displays for advertisement, in addition to the above-described examples.

It should be noted that a method for manufacturing a semiconductor device according to the above-described embodiment can be combined with an element transfer technique.

Specifically, such a technique is applied to the above-described embodiment to form a semiconductor device on a first substrate from which an element is to be transferred, and thereafter the semiconductor device is transferred (moved) onto a second substrate to which an element is to be transferred.

As a result, as the first substrate, a substrate having conditions (e.g., shape, size and physical characteristics) advantageous for semiconductor film formation and subsequent element formation can be used.

A fine and quality semiconductor element can thus be formed on the first substrate.

As the second substrate, a substrate having a large area can be used without restrictions in the element formation process, and it becomes possible to use a desired one among a wide range of substrates including inexpensive substrates made of synthetic resin, soda glass and the like and plastic films having flexibility.

Consequently, a fine and quality thin film semiconductor element can be formed easily (at low cost) on a large-area substrate.

The entire disclosure of Japanese Patent Application Nos: 2006-212916, filed Aug. 4, 2006 and 2007-13131-5, filed May 17, 2007 are expressly incorporated by reference herein.

What is claimed is:

1. A semiconductor device, comprising:
a transistor with a semiconductor film formed above a substrate, the substrate having at least one insulating surface;
a source electrode coupled to a source region of the transistor; and
a drain electrode coupled to a drain region of the transistor;
the source region and the drain region of the transistor being formed of a plurality of substantially single-crystal grains contained in the semiconductor film;
each of the plurality of substantially single-crystal grains being formed corresponding to one of a plurality of recesses formed in the substrate;
one of electrical coupling between the drain region and the drain electrode and electrical coupling between the source region and the source electrode being made by using a conductive material disposed in a contact hole;
an area of one of the plurality of substantially single-crystal grains being smaller than a sectional area of the contact hole.

2. A semiconductor device, comprising:
a transistor with a semiconductor film formed above a substrate, the substrate having at least one insulating surface;
a source electrode coupled to a source region of the transistor; and
a drain electrode coupled to a drain region of the transistor;
the source region and the drain region of the transistor being formed of a plurality of substantially single-crystal grains contained in the semiconductor film;
each of the plurality of substantially single-crystal grains being formed corresponding to one of a plurality of recesses formed in the substrate;
the drain region and the drain electrode or the source region and the source electrode being electrically coupled through a conductive material disposed in a plurality of contact holes.

3. The semiconductor device according to claim 2,
a total sectional area of the plurality of contact holes being larger than an area of one of the plurality of substantially single-crystal grains.

4. The semiconductor device according to claim 2,
an area of one of the plurality of substantially single-crystal grains being equal to or larger than an area of one of the plurality of contact holes.

5. A semiconductor device, comprising:
a transistor with a semiconductor film formed above a substrate, the substrate having at least one insulating surface;
a source electrode coupled to a source region of the transistor; and
a drain electrode coupled to a drain region of the transistor;
the source region and the drain region of the transistor being formed of a plurality of substantially single-crystal grains contained in the semiconductor film;
each of the plurality of substantially single-crystal grains being formed corresponding to one of a plurality of recesses formed in the substrate;
one of electrical coupling between the drain region and the drain electrode and electrical coupling between the source region and the source electrode being made by a conductive material disposed in a contact hole;
the conductive material being in contact with at least two of the plurality of substantially single-crystal grains.

6. The semiconductor device according to claim 5,
the conductive material being in contact with a grain boundary made by one substantially single-crystal grain of the two of the plurality of substantially single-crystal grains and all substantially single-crystal grains in contact with the one substantially single-crystal grain.

7. The semiconductor device according to claim 2,
the conductive material provided in a first one of the plurality of contact holes being in contact with at least part of a first one of the plurality of substantially single-crystal grains and
the conductive material provided in a second one of the plurality of contact holes that being different from the first one of the plurality of contact holes is in contact with at least part of a second one of the plurality of substantially single-crystal grains that is different from the first one of the plurality of substantially single-crystal grains.
